(19) United States
(12) Patent Application Publication
(10) Pub. No.: US 2013/0200376 A1
(43) Pub. Date: Aug. 8, 2013

(54) TRANSISTOR AND SEMICONDUCTOR DEVICE

(71) Applicant: Semiconductor Energy Laboratory Co., Ltd., Atsugi-shi (JP)

(72) Inventors: Shunpei YAMAZAKI, Setagaya (JP); Daisuke MATSUBAYASHI, Atsugi (JP)

(73) Assignee: SEMICONDUCTOR ENERGY LABORATORY CO., LTD., Atsugi-shi (JP)

(21) Appl. No.: 13/755,330

(22) Filed: Jan. 31, 2013

(30) Foreign Application Priority Data
Feb. 3, 2012 (JP) 2012-022445

(51) Int. Cl. H01L 29/786

(52) U.S. Cl. CPC H01L 29/78693
USPC 257/57

(57) ABSTRACT

A transistor which is resistant to a short-channel effect is provided. A semiconductor which leads to the following is used in a junction portion between a source and a semiconductor layer and a junction portion between a drain and the semiconductor layer: a majority carrier density nₛ^{S} of a source-side region satisfies a relation of Formula (1):

$${n}_{i} Exp [ \frac{e ( {φ}_{s}^{S} - {φ}_{F 0} )}{kT} ] ≦ {n}_{s}^{S} ≦ {n}_{i} Exp [ \frac{{E}_{g}}{2 kT} ] \qquad ( 1 )$$

and a majority carrier density nₛ^{D} of a drain-side region satisfies a relation of Formula (2):

$${n}_{i} Exp [ \frac{e ( {φ}_{s}^{D} - {φ}_{F 0} )}{kT} ] ≦ {n}_{s}^{D} ≦ {n}_{i} Exp [ \frac{{E}_{g}}{2 kT} ] . \qquad ( 2 )$$

The use of the semiconductor suppresses a DIBL effect.

### BACKGROUND OF THE INVENTION

1. Field of the Invention

The present invention relates to a transistor and a semiconductor device.

Note that a semiconductor device in this specification refers to all devices that can function by utilizing semiconductor characteristics, and electro-optic devices, semiconductor circuits, and electronic appliances are all semiconductor devices.

2. Description of the Related Art

To improve performance of a semiconductor integrated circuit, an improvement in performance of a transistor which is a component of the semiconductor integrated circuit is necessary. An improvement in element performance of a transistor formed using a silicon material or the like has been carried out so far by a reduction in size of the transistor. However, physical limits of the reduction in size have been recognized in recent years. Above all, it is considered that suppression of a short-channel effect is an important object.

Examples of adversary effects of a short-channel effect caused by a reduction in the gate length of a transistor upon the transistor include a reduction in threshold voltage, deterioration in subthreshold swing, undersaturation of a drain current which occurs even when a drain voltage exceeds a pinch-off voltage, flow of a drain current (punch-through current) which occurs even when the gate voltage is 0 V, and the like.

The subthreshold swing refers to a gate voltage which is necessary to increase the drain current by one digit. As the subthreshold swing is reduced, current rises more sharply and switching characteristics become better. Therefore, the punch-through current in the case where the subthreshold swing is small is smaller than that in the case where the subthreshold swing is large, under the condition that the threshold voltages are the same in both cases. When a drain induced barrier lowering (DIBL) effect is generated, the subthreshold swing of a transistor deteriorates and switching is not conducted sharply.

A DIBL effect refers to the one which brings about the following situation where an energy barrier in a junction portion of a source and a semiconductor layer is reduced owing to an influence by application of the drain voltage, so that a punch-through current flows and the subthreshold characteristics are degraded. An increase in the width of a depletion layer of a region on the drain side (hereinafter referred to as a drain-side region) leads to a large voltage drop in a region on the source side (also referred to as a source-side region). In a short-channel transistor, which is susceptible to a DIBL effect, as the width of a depletion layer of the drain-side region is increased, an energy barrier in a junction portion of the source and the semiconductor layer is reduced and an effective channel length (the length of an effective channel region) is reduced, which causes a punch-through current to be increased. The width of the depletion layer of the drain-side region, the width of a depletion layer of the source-side region, and the effective channel length greatly affect the element performance of the short-channel transistor.

As an example of a transistor in which a short-channel effect is suppressed, a MOS transistor in which a bottom portion of a gate is in contact with a gate oxide film is proposed (Patent Document 1). The bottom portion is formed of a material having an uneven work function along the length of a channel between a source-side region and a drain-side region.

### REFERENCE

### Patent Document

[Patent Document 1] Japanese Translation of PCT International Application No. 2009-519589

### SUMMARY OF THE INVENTION

As a principle for reducing in the size of a transistor while suppressing a short-channel effect, the scaling law is given, for example. However, when scaling is performed on a transistor according to the scaling law, scaling cannot be performed on a power supply voltage as it is, and thus a high drain voltage is applied to the channel region of the short-channel transistor. An increase in the width of the depletion layer of the drain-side region depending on the drain voltage results in a reduction in the element performance of the transistor.

For example, in the case of a transistor formed using a silicon semiconductor, a layer having no carrier (depletion layer) is formed in a junction portion of a source and a semiconductor layer and a junction portion of a drain and the semiconductor layer. This is because electrons of the source flow into the semiconductor layer and holes of the semiconductor layer flow into the source, so that electrons and holes are combined with each other in the vicinity of the junction portion to disappear. The width L_{D}^{Si} of a depletion layer (hereinafter referred to as a depletion layer width L_{D}^{Si}) which is formed in the junction portion of the drain and the semiconductor layer is represented as the following formula. Note that N_{A} in the following formula represents an acceptor density of the semiconductor layer (p).

$${L}_{D}^{Si} = \sqrt{1 + \frac{{V}_{SD}^{D}}{{v}^{D}}} \times \sqrt{\frac{2 ɛ {v}^{D}}{{eN}_{A}}}$$

$$( where {v}^{D} ≡ \frac{{E}_{g}}{2 e} + {φ}_{F 0} - {φ}_{s}^{D} )$$

In the case of the transistor formed using a silicon semiconductor, L_{D}^{Si} is proportional to (v^{D})^{1/2}. ev^{D} is substantially the same as an energy barrier in the junction portion of the drain (n⁺) and the semiconductor layer (p). These show that the depletion layer width L_{D}^{Si} of the drain-side region of the transistor formed using a silicon semiconductor is largely dependent on the drain voltage V_{SD}. As shown in FIGS. 7A and 7B, in the transistor formed using a silicon semiconductor, when the channel length is reduced, the depletion layer width L_{D}^{Si} is easily increased in response to a minute change in the drain voltage, which easily generates a DIBL effect.

Thus, an object of one embodiment of the present invention is to provide a transistor which is resistant to a short-channel effect.

Further, an object of one embodiment of the present invention is to improve the element characteristics of a transistor.

A semiconductor whose major carrier density satisfies a certain density range is used in a junction portion of a source or a drain and a semiconductor layer, thereby suppressing a DIBL effect.

One embodiment of the present invention disclosed in this specification is a transistor including a source and a drain provided in contact with a semiconductor layer and a gate provided over the semiconductor layer with a gate insulating layer positioned therebetween. In the transistor, a channel region is formed in a region of the semiconductor layer which overlaps with the gate; the channel region includes a source-side region, an effective channel region, and a drain-side region; and a majority carrier density nₛ^{S} of the source-side region satisfies a relation of Formula (1), a majority carrier density nₛ^{D} of the drain-side region satisfies a relation of Formula (2), and the length L_{D} of the drain-side region is represented as Formula (3) where a length of the drain-side region is L_{D}, a voltage drop in the drain-side region is V_{SD}^{D}, a difference between an energy barrier of the drain-side region and a product of the voltage drop in the drain-side region and an elementary charge is ev^{D}, a Fermi potential at an interface between the source and the source-side region is φ_{F0}, an intrinsic electron density is nᵢ, a surface potential at an interface between the effective channel region and the drain-side region is φₛ^{D}, a surface potential at an interface between the effective channel region and the source-side region is φₛ^{S}, a band gap of the semiconductor layer is E_{g}, a dielectric constant of the semiconductor layer is ∈, the elementary charge is e, a Boltzmann constant is k, and an absolute temperature is T.

$$\begin{matrix}{n}_{i} Exp [ \frac{e ( {φ}_{s}^{S} - {φ}_{F 0} )}{kT} ] ≦ {n}_{s}^{S} ≦ {n}_{i} Exp [ \frac{{E}_{g}}{2 kT} ] & ( 1 ) \\ {n}_{i} Exp [ \frac{e ( {φ}_{s}^{D} - {φ}_{F 0} )}{kT} ] ≦ {n}_{s}^{D} ≦ {n}_{i} Exp [ \frac{{E}_{g}}{2 kT} ] & ( 2 ) \\ {L}_{D} = \sqrt{1 + \frac{{V}_{SD}^{D}}{{v}^{D}}} \sqrt{\frac{2 ɛ kT}{{e}^{2} {n}_{s}^{D}}} Arc Cos \{ Exp [ - \frac{{v}^{D}}{2 kT} ] \} & ( 3 )\end{matrix}$$

In the above structure, the length of the channel region is preferably greater than or equal to 5 nm and less than or equal to 500 nm.

In the above structure, a surface steady-state current density Jₛ of the transistor is preferably represented as Formula (4) where the electron mobility is μ, the drain voltage is V_{SD}, and the length of the effective channel region is L′.

$${J}_{s} = - \frac{μ e {n}_{s}^{S} {V}_{SD}}{{f}_{D} {L}_{D} + L ’ {v}_{SD}} \\ ( where {f}_{D} ≡ \frac{1}{2} ( 1 + \frac{Sin 2 {θ}_{D}}{2 {θ}_{D}} ) , {v}_{SD} ≡ \frac{e {V}_{SD}}{kT} ) \qquad ( 4 )$$

In the above structure, the semiconductor layer is preferably an oxide semiconductor.

In this specification, the semiconductor layer is divided into three regions, i.e., the source-side region, the effective channel region, and the drain-side region.

In this specification, the effective channel length refers to the length of the effective channel region, and the channel length refers to the sum of the length of the drain-side region, the length of the source-side region, and the length of the effective channel region.

Note that a region whose gate voltage is lower than or equal to the threshold voltage is defined as a subthreshold region in this specification.

Even in the case of a short-channel transistor, by an increase in the effective channel length, the transistor can be less influenced by a DIBL effect.

### BRIEF DESCRIPTION OF THE DRAWINGS

FIG. 1 illustrates a transistor model in a quasi two-dimensional system.

FIG. 2 shows an energy band in a channel direction.

FIG. 3 is a graph of calculation results.

FIG. 4 is a graph of calculation results.

FIG. 5 is a graph of calculation results.

FIG. 6 is a graph of calculation results.

FIGS. 7A and 7B each show an energy band in a silicon transistor.

FIGS. 8A and 8B illustrate a structural example of a transistor.

FIGS. 9A and 9B each illustrate a structural example of a transistor.

### DETAILED DESCRIPTION OF THE INVENTION

Embodiments will be described in detail with reference to the accompanying drawings. Note that the present invention is not limited to the following description, and it will be easily understood by those skilled in the art that various changes and modifications can be made without departing from the spirit and scope of the invention. Therefore, the present invention should not be construed as being limited to the description in the following embodiments. Note that in the structures of the invention described below, the same portions or portions having similar functions are denoted by the same reference numerals in different drawings, and description of such portions is not repeated.

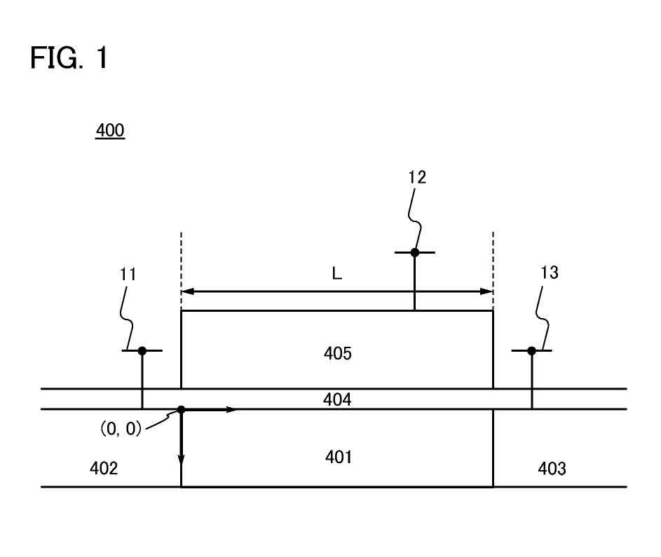

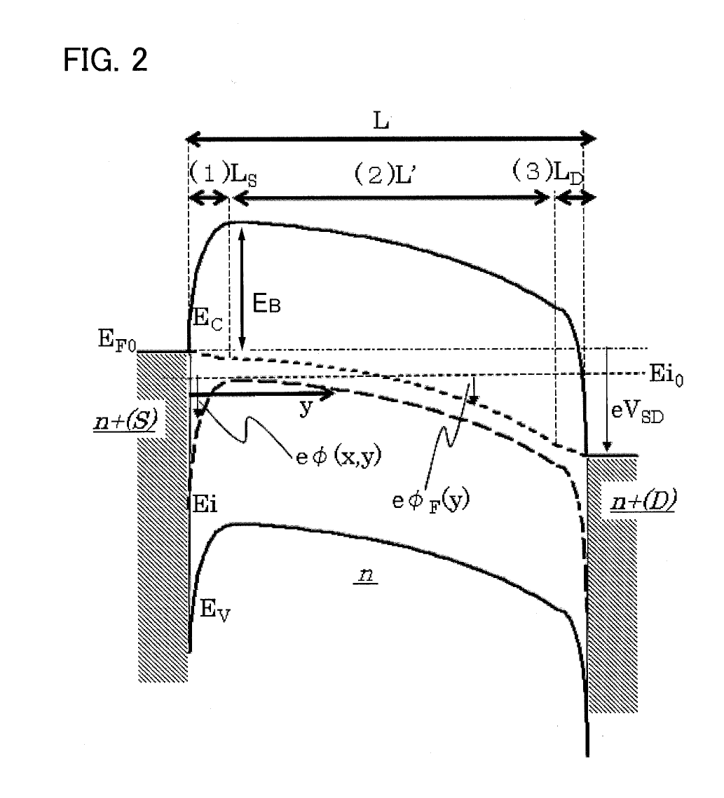

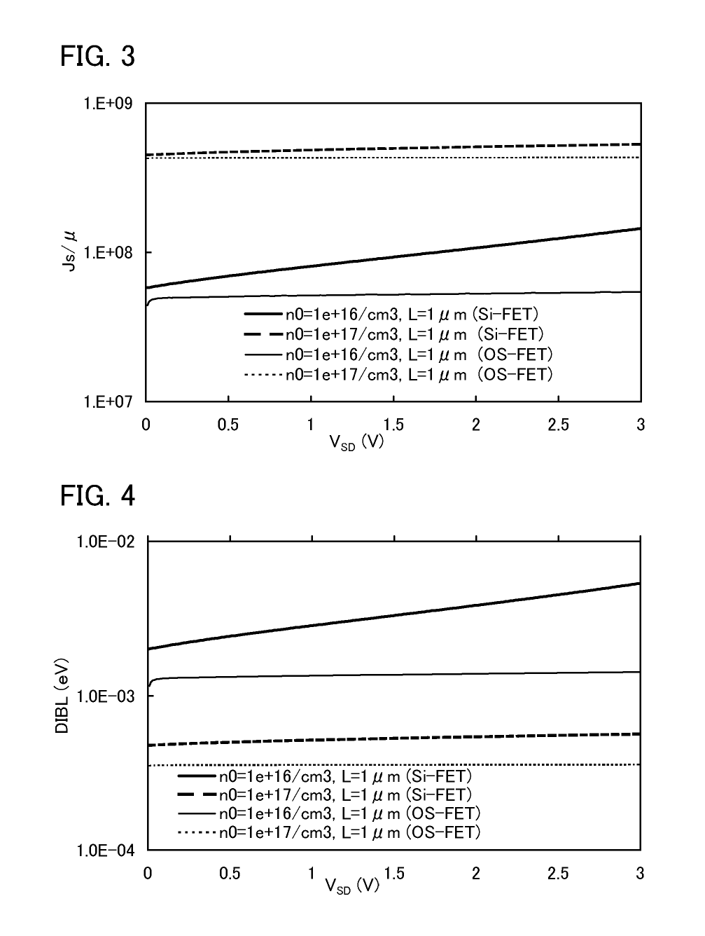

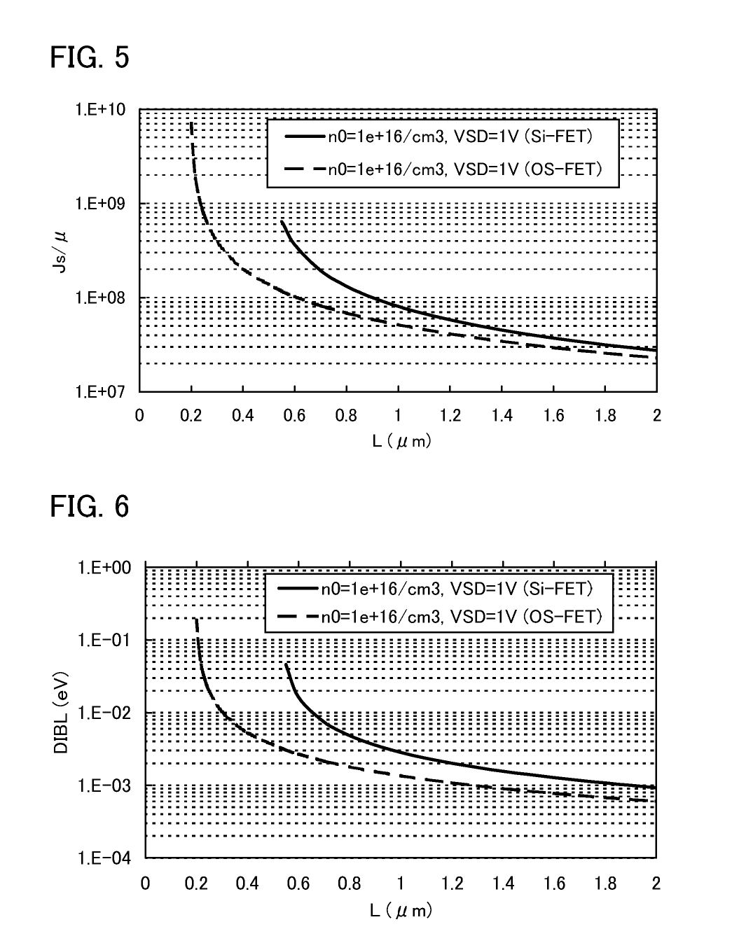

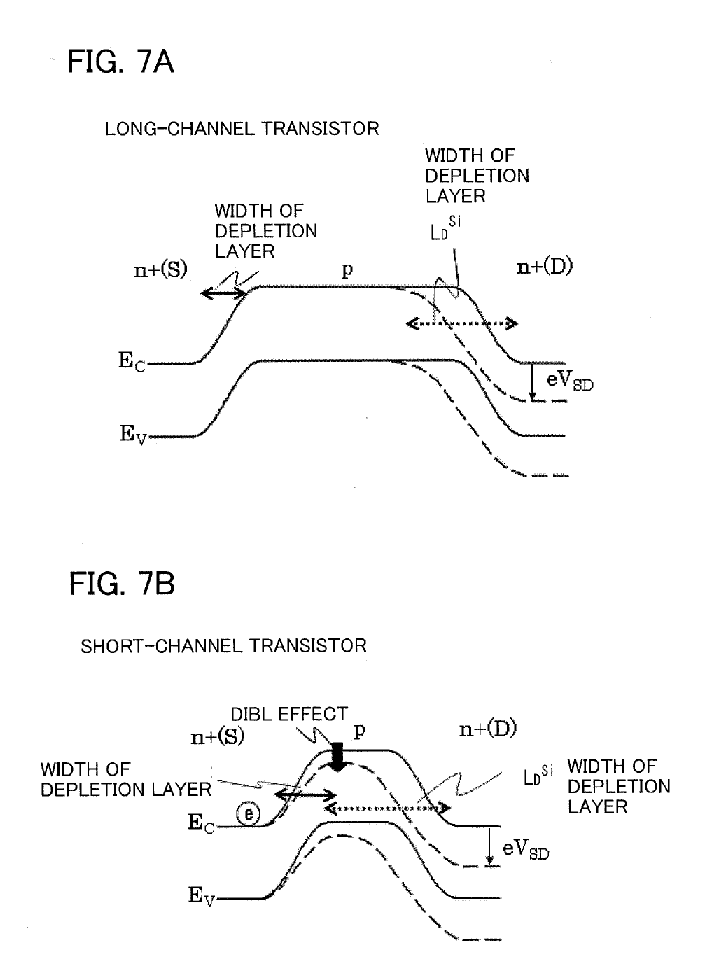

When a semiconductor material whose majority carriers satisfy a certain constant density range is used in a junction portion of a source or a drain and a semiconductor layer in a transistor, a DIBL effect can be suppressed, which is described using FIG. 1, FIG. 2, FIG. 3, FIG. 4, FIG. 5, and FIG. 6.

In the case where an oxide semiconductor is used for a semiconductor layer, the junction portion of a source (n⁺) and the semiconductor layer (n) is an (n⁺)-(n) junction, and in a similar manner, the junction portion of a drain (n⁺) and the semiconductor layer (n) is an (n⁺)-(n) junction. Although the following description explains an example in which an oxide semiconductor is used for the semiconductor layer, a semiconductor which is used for the semiconductor layer is not limited to an oxide semiconductor as long as majority carriers exist in the semiconductor in the vicinity of the junction portion.

For example, a length L_{D}^{OS} of a drain-side region of an oxide semiconductor which is formed in the junction portion of a drain and a semiconductor layer and in which a majority carrier exists is represented as the following formula.

$${L}_{D}^{OS} = \sqrt{1 + \frac{{V}_{SD}^{D}}{{v}^{D}}} \sqrt{\frac{2 ɛ kT}{{e}^{2} {n}_{s}^{D}}} ArcCos \{ Exp [ - \frac{{v}^{D}}{2 kT} ] \}$$

A method for deriving the length L_{D}^{OS} of the drain-side region of the oxide semiconductor in the case of a transistor 400 which includes an oxide semiconductor in a semiconductor layer and is modeled in a quasi two-dimensional system is described below. In addition, a method for deriving space distribution of a potential φ and a Fermi potential φ_{F} in the semiconductor layer on the basis of the quasi two-dimensional system model of the transistor 400 is described. Further, a method for deriving a current flowing through the channel region (punch-through current) and a voltage drop in the source-side region is described using the obtained potential φ and Fermi potential φ_{F}. Then, in consideration of the punch-through current and the voltage drop in the source-side region which are derived, degradation in the characteristics of a short-channel transistor due to the DIBL effect is discussed. Note that the length of a region which can be controlled by the gate voltage (the effective channel region) in the transistor is determined by the voltage drop in the source-side region at the time of application of a drain voltage, that is, by the extent of the DIBL effect. Thus, the voltage drop in the source-side region is examined.

Note that when the gate voltage is lower than or equal to the threshold voltage (in the subthreshold region), the transistor is in an off state, and thus an influence by the DIBL effect can be significantly increased. Accordingly, to examine the punch-through current, the length of the drain-side region, and the like in the case of the gate voltage lower than or equal to the threshold voltage can be regarded as one reference for determining whether or not the transistor is resistant to a short-channel effect. Therefore, model calculation in the quasi two-dimensional system in this specification is carried out only in the case where the gate voltage is lower than or equal to the threshold voltage.

FIG. 1 illustrates the quasi two-dimensional model of the transistor 400. The transistor 400 includes a source 402 and a drain 403 which are provided in contact with a semiconductor layer 401, and a gate 405 which is provided over the semiconductor layer 401 with a gate insulating layer 404 positioned therebetween. The source 402 is electrically connected to a first terminal 11. The gate 405 is electrically connected to a second terminal 12. The drain 403 is electrically connected to a third terminal 13.

The source 402 and the drain 403 are each an n⁺ region, and the semiconductor layer 401 is an n region (formed using an oxide semiconductor here).

A ground potential (GND) is applied to the first terminal 11. A gate voltage (V_{G}) is applied to the second terminal 12. A drain voltage (V_{SD}) is applied to the third terminal 13.

The origin of (x, y) coordinates in the quasi two-dimensional system is set to a point where the source 402, the semiconductor layer 401, and the gate insulating layer 404 are in contact with one another. Note that a direction perpendicular to the plane of paper of FIG. 1 is the z axis, and the quasi two-dimensional model illustrated in FIG. 1 continues evenly in the z-axis direction.

A channel length L is regarded as the same as the length of the gate 405 in the calculation, for simplification.

The gate 405 is regarded as having the same work function as the semiconductor layer 401. That is, when 0 V is applied to the third terminal 13 (the drain voltage V_{SD}) and the second terminal 12 (the gate voltage V_{G}), the semiconductor layer has a flat band.

To derive the space distribution of the potential φ and the Fermi potential φ_{F} in the semiconductor layer in the quasi two-dimensional model shown in FIG. 1 described above, the following three simultaneous equations are solved.

$$\begin{matrix}\frac{{\partial }^{2} φ}{\partial {x}^{2}} + \frac{{\partial }^{2} φ}{\partial {y}^{2}} = - \frac{ρ}{ɛ} & ( Poissons ' s equation ) \\ \begin{matrix}{J}_{y} = - μ en \frac{\partial φ}{\partial y} + eD \frac{\partial n}{\partial y} \\ = - μ en \frac{\partial {φ}_{F}}{\partial y}\end{matrix} & ( Charge transfer equation ) \\ e \frac{\partial n}{\partial t} = - \frac{\partial {J}_{y}}{\partial y} = 0 & ( Current continuity equation )\end{matrix}$$

Next, an energy band diagram is shown in FIG. 2. As shown in FIG. 2, the semiconductor layer is regarded as being divided into three regions, i.e., (1) the source-side region (0<y<L_{S}), (2) the effective channel region (L_{S}<y<L_{S}+L′), and (3) the drain-side region (L_{S}+L′<y<L_{S}+L′+L_{D}).

Parameters are defined as follows: a potential of the semiconductor layer is φ(x, y); a Fermi potential of the semiconductor layer is φ_{F}(y); the length of the source-side region is L_{S}; the length of the channel region is L; the length of the effective channel region is L′; the length of the drain-side region is L_{D}; an intrinsic energy level of the semiconductor layer is Eᵢ₀, an elementary charge is e; an intrinsic electron density of the semiconductor layer is nᵢ; the Boltzmann constant is k; an absolute temperature is T; a dielectric constant of the semiconductor layer is ∈; electron mobility is μ; an electron diffusion coefficient is D; and a band gap of the oxide semiconductor layer is E_{g}.

Only a surface of the semiconductor layer is taken into consideration in this calculation. Therefore, the x-coordinate of the potential φ(x, y) can be set as 0.

The Fermi potential φ_{F}(y) is calculated on the assumption that it is not dependent on the x-coordinate.

When the third terminal 13 (V_{SD})=0 V and the second terminal 12 (V_{G})=0 V, the potential φ(x, y) is equal to the intrinsic energy level Eᵢ₀ at coordinates (0, 0) and thus is defined as follows.

φ(0,0)=Eᵢ₀

When the third terminal 13 (V_{SD})≠0 V and the second terminal 12 (V_{G})≠0 V, the potential φ(x, y) can be regarded as a difference between the intrinsic energy level Eᵢ₀ at the coordinates (0, 0) and the intrinsic energy level Eᵢ(x, y) at coordinates (x, y) and thus is defined as follows.

φ(x,y)=Eᵢ₀−Eᵢ(x,y)

The Fermi potential φ_{F}(y) in the case of y=0 is defined as follows.

φ_{F}(0)=Eᵢ₀−E_{F}(0)=φ_{F0}

Fermi energy E_{F}(y) in the case of y=0, which changes in the y-axis direction, is defined as follows.

E_{F}(0)=E_{F0}

Therefore, the Fermi potential φ_{F}(y) can be regarded as a difference between the intrinsic energy level Eᵢ₀ and the Fermi energy E_{F}(y) changing in the y-axis direction and thus can be defined as follows.

φ_{F}(y)=Eᵢ₀−E_{F}(y)

Here, in the oxide semiconductor, majority carriers exist in the junction portion of the source and the semiconductor layer and in the junction portion of the drain and the semiconductor layer. Therefore, Fermi energy E_{F0} is located on a higher energy side than the intrinsic energy level Eᵢ₀, and φ_{F}(0) satisfies a relation of the following formula.

φ_{F}(0)=φ_{F0}<0

Since majority carriers exist in the junction portions of the oxide semiconductor, a total charge density ρ(x, y) in coordinates (x, y) of Poisson's equation is obtained when negative charge of an electron density n(x, y) and positive charge of a donor density N_{D} are taken into consideration. In addition, it is possible that contribution of the donor density N_{D} in the source-side region in contact with the n⁺ region and in the drain-side region in contact with the n⁺ region is not taken into consideration, and thus the total charge density ρ(x, y) can be represented as the following formula.

ρ(x,y)=−en(x,y)+eN_{D}≅−en(x,y)

When the above formula is substituted into Poisson's equation, the following formula can be obtained.

$$\frac{{\partial }^{2} φ}{\partial {x}^{2}} = - \frac{ρ}{ɛ} = \frac{e}{ɛ} n ( x , y )$$

The electron density n(x,y) can be represented as the following formula using the potential φ(x, y) and the Fermi potential φ_{F}(y).

$$n ( x , y ) = {n}_{i} Exp [ \frac{e ( φ ( x , y ) - {φ}_{F} ( x , y ) )}{kT} ]$$

Einstein relation is described below.

$$D = \frac{kT μ}{e}$$

When the formula of the electron density n(x, y) and the Einstein relation are used, the second formula can be transformed into the third formula in the following charge transfer equation which is also described above.

$${J}_{y} = - μ en \frac{\partial φ}{\partial y} + eD \frac{\partial n}{\partial y} = - μ en \frac{\partial {φ}_{F}}{\partial y} \qquad ( Charge transfer equation )$$

Since the Fermi potential φ_{F}(y) is regarded as being dependent only on the y-axis direction, considering only a current density J_{y} in the y-axis direction, the following current continuity equation is obtained. Note that the right side of the equation is set to 0 because a steady state is taken into consideration.

$$e \frac{\partial n}{\partial t} = - \frac{\partial {J}_{y}}{\partial y} = 0$$

Since the semiconductor layer is regarded as being divided into (1) the source-side region, (2) the effective channel region, and (3) the drain-side region, a boundary condition in each region can be represented as follows.

(1) The source-side region: 0<y<L_{S}

(2) The effective channel region: L_{S}<y<L_{S}+L′

(3) The drain-side region: L_{S}+L′<y<L_{S}+L′+L_{D} (=L)

Majority carriers exist in the junction portion of the source (n⁺) and the semiconductor layer (n) and the junction portion of the drain (n⁺) and the semiconductor layer (n), and these junction portions each have a high electron density; therefore, the following formula is satisfied.

ρ=−en

In (1) the source-side region and (3) the drain-side region, the electron density cannot be controlled by the gate voltage V_{G}, and thus the following formula is satisfied.

$$\frac{\partial φ}{\partial x} ≅ 0$$

Note that (2) the effective channel region is a region whose electron density can be controlled by the gate voltage V_{G}.

The boundary condition in terms of the potential φ(x, y) is as follows.

$$\{ \begin{matrix}φ ( 0 , 0 ) = \frac{{E}_{g}}{2 e} + {φ}_{F 0} \\ φ ( 0 , {L}_{s} ) = {φ}_{s}^{S} + {V}_{SD}^{S} \\ φ ( 0 , {L}_{S} + {L}^{′} ) = {φ}_{s}^{D} + {V}_{SD}^{S} + {V}_{SD}^{′} \\ φ ( 0 , {L}_{S} + {L}^{′} + {L}_{D} ) = \frac{{E}_{g}}{2 e} + {φ}_{F 0} + {V}_{SD}^{S} + {V}_{SD}^{′} + {V}_{SD}^{D}\end{matrix}$$

Note that in this calculation, a potential φ(0, y) of the effective channel region is represented as the sum of a surface potential φₛ and a voltage drop.

Here, a voltage drop in the source-side region is set as V_{SD}^{S}, a voltage drop in the drain-side region is set as V_{SD}^{D}, and a voltage drop in the effective channel region is set as V_{SD}′. Accordingly, the following formula is satisfied in terms of the drain voltage V_{SD}.

V_{SD}=V_{SD}^{S}+V_{SD}′+V_{SD}^{D}

The voltage drop V_{SD}^{S} in the source-side region is a sign indicating the extent of the DIBL effect.

An energy barrier E_{B} in the junction portion of the source (n⁺) and the semiconductor layer (n) is represented as the following formula.

$${E}_{B} = \frac{{E}_{g}}{2} + e {φ}_{F 0} - e {φ}_{s}^{S} - e {V}_{SD}^{S}$$

This formula indicates that when the drain voltage V_{SD} is applied to the third terminal 13, the height of the energy barrier is reduced by eV_{SD}^{S}. In other words, as the influence by the DIBL effect becomes larger, eV_{SD}^{S} is increased; as a result, the energy barrier is largely reduced.

Majority carriers exist in the vicinity of the junction portion of the oxide semiconductor layer. Therefore, when φₛ>0, a surface of the semiconductor layer in the case of x=0 is in an electron accumulated state, so that current flows in the channel region. On the other hand, when φₛ<0, the surface of the semiconductor layer is in an electron depleted state, and current does not flow. Therefore, in the subthreshold region where the DIBL effect is examined in this calculation, a relation of φₛ≦0 including φₛ=0 is satisfied.

A depletion layer is formed in the vicinity of a junction portion of a silicon semiconductor layer. Therefore, in the case of p-type silicon, the Fermi energy E_{F0} is located on the lower energy side than the intrinsic energy level Eᵢ₀. Therefore, φ_{F0}>0 is satisfied. In addition, when φₛ>2φ_{F0}, a surface of the semiconductor layer is in a strong inversion state, so that current flows in the channel region. On the other hand, when φₛ<2φ_{F0}, current does not flow. Therefore, in the subthreshold region where the DIBL effect is examined in this calculation, a relation of φₛ≦2φ_{F0} including φₛ=2φ_{F0} is satisfied.

On the other hand, the boundary condition in terms of the Fermi potential φ_{F} is as follows.

$$\{ \begin{matrix}{φ}_{F} ( 0 ) = {φ}_{F 0} \\ {φ}_{F} ( {L}_{S} ) = {φ}_{F 0} + {V}_{SD}^{S} \\ {φ}_{F} ( {L}_{S} + {L}^{′} ) = {φ}_{F 0} + {V}_{SD}^{S} + {V}_{SD}^{′} \\ {φ}_{F} ( {L}_{S} + {L}^{′} + {L}_{D} ) = {φ}_{F 0} + {V}_{SD}^{S} + {V}_{SD}^{′} + {V}_{SD}^{D}\end{matrix}$$

When the channel length L is fixed, as the length L_{S} of the source-side region and the length L_{D} of the drain-side region are increased, the length L′ of the effective channel region (also referred to as an effective channel length) is reduced. Therefore, to increase the effective channel length L′, that is, the length of (2) the effective channel region, which can be controlled by the gate voltage V_{G}, it is preferable that the length L_{S} of the source-side region and the length L_{D} of the drain side be reduced.

Since electrons which are transferred from the source and the drain are accumulated in (1) the source-side region and (3) the drain-side region of the semiconductor layer, the following Poisson's equation should be solved to obtain the potential φ and the Fermi potential φ_{F} in the regions.

$$\frac{{\partial }^{2} φ}{\partial {x}^{2}} = \frac{ρ}{ɛ} n = \frac{e}{ɛ} {n}_{i} Exp [ \frac{e ( φ - {φ}_{F} )}{kT} ]$$

First, focusing on (1) the source-side region, the length L_{S} of (1) the source-side region is derived. A method for deriving the length L_{S} is described below.

When the drain voltage V_{SD}=0 V, that is, when the Fermi potential φ_{F}(0)=φ_{F0}, which is constant, a solution φ which satisfies Poisson's equation can be calculated by solving the following formula on the basis of the boundary condition y=L_{S}.

$$\frac{\partial φ ( 0 , y )}{\partial y} {\vert}_{y = {L}_{S}} = 0$$

In (1) the source-side region where 0<y<L_{S}, eφ(0, y) can be represented as the following formula.

$$e φ ( 0 , y ) = e {φ}_{s}^{S} - 2 kT Ln Cos [ \sqrt{\frac{{e}^{2} {n}_{s}^{S}}{2 ɛ kT}} ( y - {L}_{S} ) ]$$

Further, eφ_{F}(y) can be represented as the following formula.

eφ_{F}(y)=eφ_{F0}

Note that a majority carrier density nₛ^{S} of the source-side region can be represented as follows.

$${n}_{s}^{S} = {n}_{i} Exp [ \frac{e ( {φ}_{s}^{S} - {φ}_{F 0} )}{kT} ]$$

Referring to the formula, function forms of the potential φ and the Fermi potential φ_{F} in the case where the drain voltage V_{SD} is greater than 0 V and finite are set as follows.

$$e φ ( 0 , y ) = {C}_{1} - 2 {kTC}_{2} Ln Cos [ \frac{1}{{c}_{S}} \sqrt{\frac{{e}^{2} {n}_{s}^{S}}{2 ɛ kT}} ( y - {L}_{S} ) ]$$

$$e {φ}_{F} ( y ) = {C}_{3} - 2 {kTC}_{4} Ln Cos [ \frac{1}{{c}_{S}} \sqrt{\frac{{e}^{2} {n}_{s}^{S}}{2 ɛ kT}} ( y - {L}_{S} ) ]$$

Here, C₁, C₂, C₃, C₄, and c_{S} are undetermined coefficients and are determined so as to satisfy the boundary condition. First, from the boundary condition in the case of y=L_{S}, C₁ and C₃ are determined as follows.

eφ(0,L_{S})=e(φₛ^{S}+V_{SD}^{S})=C₁

eφ_{F}(L_{S})=e(φ_{F0}+V_{SD}^{S})=C₃

Next, from the boundary condition in the case of y=0, the following formula is satisfied in terms of the potential φ.

$$e φ ( 0 , 0 ) = \frac{{E}_{g}}{2} + e {φ}_{F 0} = {C}_{1} - 2 {kTC}_{2} Ln Cos [ \frac{1}{{c}_{S}} \sqrt{\frac{{e}^{2} {n}_{s}^{S}}{2 ɛ kT}} {L}_{S} ]$$

Therefore, C₂ can be represented as follows using c_{S}.

$${C}_{2} = - \frac{\frac{{E}_{g}}{2} + e ( {φ}_{F 0} + {φ}_{s}^{S} - {V}_{SD}^{S} )}{2 kT Ln Cos [ \frac{1}{{c}_{S}} \sqrt{\frac{{e}^{2} {n}_{s}^{S}}{2 ɛ kT}} {L}_{S} ]}$$

Similarly, from the boundary condition in the case of y=0, the following formula is satisfied in terms of the Fermi potential φ_{F}.

$$e {φ}_{F} ( 0 ) = e {φ}_{F 0} = {C}_{3} - 2 {kTC}_{4} Ln Cos [ \frac{1}{{c}_{S}} \sqrt{\frac{{e}^{2} {n}_{s}^{S}}{2 ɛ kT}} {L}_{S} ]$$

Therefore, C₄ can be represented as follows also using c_{S}.

$${C}_{4} = \frac{{V}_{SD}^{S}}{2 kT Ln Cos [ \frac{1}{{c}_{S}} \sqrt{\frac{{e}^{2} {n}_{s}^{S}}{2 ɛ kT}} {L}_{S} ]}$$

The potential φ and the Fermi potential φ_{F} need to satisfy Poisson's equation. Thus, the function forms set as described above are substituted into Poisson's equation to derive an undetermined relation among C₂, C₄, and c_{S}. The left side of the Poisson's equation becomes as follows.

$$\frac{{\partial }^{2} φ}{\partial {y}^{2}} = \frac{e}{ɛ} {n}_{s}^{S} \frac{{C}_{2}}{{c}_{s}^{2}} \frac{1}{{Cos}^{2} [ \frac{1}{{c}_{S}} \sqrt{\frac{{e}^{2} {n}_{s}^{S}}{2 ɛ kT}} ( y - {L}_{S} ) ]}$$

On the other hand, the right side of the Poisson's equation becomes as follows.

$$e ( φ - {φ}_{F} ) = e ( {φ}_{s}^{S} - {φ}_{F 0} ) - 2 kT ( {C}_{2} - {C}_{4} ) Ln Cos [ \frac{1}{{c}_{S}} \sqrt{\frac{{e}^{2} {n}_{s}^{S}}{2 ɛ kT}} ( y - {L}_{S} ) ]$$

Accordingly, these are solved to provide the following formula.

$$\frac{e}{ɛ} {n}_{i} Exp [ \frac{e ( φ - {φ}_{F} )}{kT} ] = \frac{e}{ɛ} {n}_{s}^{S} \frac{1}{{Cos}^{2 ( {C}_{2} - {C}_{4} )} [ \frac{1}{{c}_{S}} \sqrt{\frac{{e}^{2} {n}_{s}^{S}}{2 ɛ kT}} ( y - {L}_{S} ) ]}$$

Comparing the coefficients on both sides, C₂−C₄ is 1. Further, the following formula is also satisfied.

$$\frac{{C}_{2}}{{c}_{S}^{2}} = 1$$

Note that C₂−C₄ can be represented as follow.

$${C}_{2} - {C}_{4} = - \frac{{ev}^{S}}{2 kT Ln Cos [ \frac{1}{{c}_{S}} \sqrt{\frac{{e}^{2} {n}_{s}^{S}}{2 ɛ kT}} {L}_{S} ]}$$

Accordingly, the value of a denominator of C₂−C₄ can be determined as follows using the relation, C₂−C₄=1.

$$2 kT Ln Cos [ \frac{1}{{c}_{S}} \sqrt{\frac{{e}^{2} {n}_{s}^{S}}{2 ɛ kT}} {L}_{S} ] = - {ev}^{S} \\ ( where {v}^{S} ≡ \frac{{E}_{g}}{2 e} + {φ}_{F 0} - {φ}_{s}^{S} )$$

As a result, C₂, C₄, and c_{S} are determined as follows.

$${C}_{2} = 1 - \frac{{V}_{SD}^{S}}{{v}^{S}}$$

$${C}_{4} = - \frac{{V}_{SD}^{S}}{{v}^{S}}$$

$${c}_{S} = \sqrt{{C}_{2}} = \sqrt{1 - \frac{{V}_{SD}^{S}}{{v}^{S}}}$$

Thus, the potential φ and the Fermi potential φ_{F} in (1) the source-side region where 0<y<L_{S} are determined as follows.

$$e φ ( 0 , y ) = e ( {φ}_{s}^{S} + {V}_{SD}^{S} ) - 2 {kTc}_{S}^{2} Ln Cos [ \frac{1}{{c}_{S}} \sqrt{\frac{{e}^{2} {n}_{s}^{S}}{2 ɛ kT}} ( y - {L}_{S} ) ]$$

$$e {φ}_{F} ( y ) = e ( {φ}_{F 0} + {V}_{SD}^{S} ) - 2 kT ( {c}_{S}^{2} - 1 ) Ln Cos [ \frac{1}{{c}_{S}} \sqrt{\frac{{e}^{2} {n}_{s}^{S}}{2 ɛ kT}} ( y - {L}_{S} ) ]$$

Actually, when V_{SD} is 0 V, V_{SD}^{D} is 0 V and thus eφ(0, y) and eφ_{F}(y) are represented as the following formulae.

$$e φ ( 0 , y ) = e {φ}_{s}^{S} - 2 kT Ln Cos [ \sqrt{\frac{{e}^{2} {n}_{s}^{S}}{2 ɛ kT}} ( y - {L}_{S} ) ]$$

$$e {φ}_{F} ( y ) = e {φ}_{F 0}$$

At the same time, the length L_{S} of (1) the source-side region can also be determined as follows using the following formula.

$$2 kT Ln Cos [ \frac{1}{{c}_{S}} \sqrt{\frac{{e}^{2} {n}_{s}^{S}}{2 ɛ kT}} {L}_{S} ] = - {ev}^{S}$$

$${L}_{S} = {L}_{S}^{OS} = {c}_{S} \sqrt{\frac{2 ɛ kT}{{e}^{2} {n}_{s}^{S}}} Arc Cos \{ Exp [ - \frac{{v}^{S}}{2 kT} ] \}$$

Next, focusing on (3) the drain-side region, the length L_{D} of (3) the drain-side region is derived. A method for deriving the length L_{D} is described below.

When the drain voltage V_{SD}=0 V, that is, when the Fermi potential φ_{F}(0)=φ_{F0}, which is constant, a solution φ which satisfies Poisson's equation can be calculated by solving the following formula on the basis of the boundary condition y=L_{S}+L′.

$$\frac{\partial φ ( 0 , y )}{\partial y} {\vert}_{y = {L}_{S} + {L}^{′}} = 0$$

In (3) the drain-side region where L_{S}+L′<y<L_{S}+L′+L_{D}, eφ(0, y) can be represented as the following formula.

$$e φ ( 0 , y ) = e {φ}_{s}^{D} - 2 kT Ln Cos [ \sqrt{\frac{{e}^{2} {n}_{s}^{D}}{2 ɛ kT}} ( y - {L}_{S} - {L}^{′} ) ]$$

Further, eφ_{F}(y) can be represented as the following formula.

$$e {φ}_{F} ( y ) = e {φ}_{F 0} \\ ( where {n}_{s}^{D} = {n}_{i} Exp [ \frac{e ( {φ}_{s}^{D} - {φ}_{F 0} )}{kT} ] )$$

Referring to the formula, function forms of the potential φ and the Fermi potential φ_{F} in the case where the drain voltage V_{SD} is greater than 0 V and finite are set as follows.

$$e φ ( 0 , y ) = {C}_{1}^{′} - 2 {kTC}_{2}^{′} Ln Cos [ \frac{1}{{c}_{D}} \sqrt{\frac{{e}^{2} {n}_{s}^{D}}{2 ɛ kT}} ( y - {L}_{S} - {L}^{′} ) ]$$

$$e {φ}_{F} ( y ) = {C}_{3}^{′} - 2 {kTC}_{4}^{′} Ln Cos [ \frac{1}{{c}_{D}} \sqrt{\frac{{e}^{2} {n}_{s}^{D}}{2 ɛ kT}} ( y - {L}_{s} - {L}^{′} ) ]$$

Here, C₁′, C₂′, C₃′, C₄′, and c_{D} are undetermined coefficients and are determined so as to satisfy the boundary condition. First, from the boundary condition in the case of y=L_{S}+L′, C₁′ and C₃′ are determined as follows.

eφ(0,L_{S}+L′)=e(φₛ^{D}+V_{SD}^{S}+V_{SD}′)=C₁′

eφ_{F}(L_{S}+L′)=e(φ_{F0}+V_{SD}^{S}+V_{SD}′)=C₃′

Next, from the boundary condition in the case of y=L, the following formula is satisfied in terms of the potential φ.

$$\begin{matrix}e φ ( 0 , L ) = \frac{{E}_{g}}{2} + e ( {φ}_{F 0} + {V}_{SD} ) \\ = {C}_{1}^{′} - 2 {kTC}_{2}^{′} Ln Cos [ \frac{1}{{c}_{D}} \sqrt{\frac{{e}^{2} {n}_{s}^{D}}{2 ɛ kT}} {L}_{D} ]\end{matrix}$$

Therefore, C₂′ can be represented as follows using c_{D}.

$${C}_{2}^{′} = - \frac{\frac{{E}_{g}}{2} + e ( {φ}_{F 0} + {V}_{SD}^{D} - {φ}_{s}^{D} )}{2 kT Ln Cos [ \frac{1}{{c}_{D}} \sqrt{\frac{{e}^{2} {n}_{s}^{D}}{2 ɛ kT}} {L}_{D} ]}$$

Similarly, from the boundary condition in the case where y=L, the following formula is satisfied in terms of the Fermi potential φ_{F}.

$$e {φ}_{F} ( L ) = e ( {φ}_{F 0} + {V}_{SD} ) = {C}_{3}^{′} - 2 {kTC}_{4}^{′} Ln Cos [ \frac{1}{{c}_{D}} \sqrt{\frac{{e}^{2} {n}_{s}^{D}}{2 ɛ kT}} {L}_{D} ]$$

Therefore, C₄′ can be represented as follows also using c_{D}.

$${C}_{4}^{′} = - \frac{{V}_{SD}^{D}}{2 kT Ln Cos [ \frac{1}{{c}_{D}} \sqrt{\frac{{e}^{2} {n}_{s}^{D}}{2 ɛ kT}} {L}_{D} ]}$$

The potential φ and the Fermi potential φ_{F} need to satisfy Poisson's equation. Thus, the function forms set as described above are substituted into Poisson's equation to derive an undetermined relation among C₂′, C₄′, and c_{D}. The left side of the Poisson's equation becomes as follows.

$$\frac{{\partial }^{2} φ}{\partial {y}^{2}} = \frac{e}{ɛ} {n}_{s}^{D} \frac{{C}_{2}^{′}}{{c}_{D}^{2}} \frac{1}{{Cos}^{2} [ \frac{1}{{c}_{D}} \sqrt{\frac{{e}^{2} {n}_{s}^{D}}{2 ɛ kT}} ( y - {L}_{S} - {L}^{′} ) ]}$$

On the other hand, the right side of the Poisson's equation becomes as follows.

$$e ( φ - {φ}_{F} ) = e ( {φ}_{s}^{D} - {φ}_{F 0} ) - 2 kT ( {C}_{2}^{′} - {C}_{4}^{′} ) Ln Cos [ \frac{1}{{c}_{D}} \sqrt{\frac{{e}^{2} {n}_{s}^{D}}{2 ɛ kT}} ( y - {L}_{S} - {L}^{′} ) ]$$

Accordingly, these are solved to provide the following formula.

$$\frac{e}{ɛ} {n}_{i} Exp [ \frac{e ( φ - {φ}_{F} )}{kT} ] = \frac{e}{ɛ} {n}_{s}^{D} \frac{1}{{Cos}^{2 ( {C}_{2}^{′} - {C}_{4}^{′} )} [ \frac{1}{{c}_{D}} \sqrt{\frac{{e}^{2} {n}_{s}^{D}}{2 ɛ kT}} ( y - {L}_{S} - {L}^{′} ) ]}$$

Comparing the coefficients on both sides, C₂′−C₄′ is 1. Further, the following formula is also satisfied.

$$\frac{{C}_{2}^{′}}{{c}_{D}^{2}} = 1$$

Note that C₂′−C₄′ can be represented as follow.

$${C}_{2}^{′} - {C}_{4}^{′} = - \frac{{ev}^{D}}{2 kT Ln Cos [ \frac{1}{{c}_{D}} \sqrt{\frac{{e}^{2} {n}_{s}^{D}}{2 ɛ kT}} {L}_{D} ]}$$

Accordingly, the value of a denominator of C₂′−C₄′ can be determined as follows using the relation, C₂′−C₄′=1.

$$2 kT Ln Cos [ \frac{1}{{c}_{D}} \sqrt{\frac{{e}^{2} {n}_{s}^{D}}{2 ɛ kT}} {L}_{D} ] = - {ev}^{D} \\ ( where {v}^{D} ≡ \frac{{E}_{g}}{2 e} + {φ}_{F 0} - {φ}_{s}^{D} )$$

As a result, C₂′, C₄′, and c_{D} are determined as follows.

$${C}_{2}^{′} = 1 + \frac{{V}_{SD}^{D}}{{v}^{D}}$$

$${C}_{4}^{′} = \frac{{V}_{SD}^{D}}{{v}^{D}}$$

$${c}_{D} = \sqrt{{C}_{2}^{′}} = \sqrt{1 + \frac{{V}_{SD}^{D}}{{v}^{D}}}$$

Thus, the potential φ and the Fermi potential φ_{F} in (3) the drain-side region where L_{S}+L′<y<L_{S}+L′+L_{D} are determined as follows.

$$e φ ( 0 , y ) = e ( {φ}_{s}^{S} + {V}_{SD}^{S} + {V}_{SD}^{′} ) - 2 {kTc}_{D}^{2} Ln Cos [ \frac{1}{{c}_{D}} \sqrt{\frac{{e}^{2} {n}_{s}^{D}}{2 ɛ kT}} ( y - {L}_{S} - {L}^{′} ) ]$$

$$e {φ}_{F} ( y ) = e ( {φ}_{F 0} - {V}_{SD}^{S} + {V}_{SD}^{′} ) - 2 kT ( {c}_{D}^{2} - 1 ) Ln Cos [ \frac{1}{{c}_{D}} \sqrt{\frac{{e}^{2} {n}_{s}^{D}}{2 ɛ kT}} ( y - {L}_{S} - {L}^{′} ) ]$$

Actually, when V_{SD} is 0 V, V_{SD}^{D} is 0 V and thus eφ(0, y) and eφ_{F}(y) are represented as the following formulae.

$$e φ ( 0 , y ) = e {φ}_{s}^{D} - 2 kT Ln Cos [ \sqrt{\frac{{e}^{2} {n}_{s}^{D}}{2 ɛ kT}} ( y - {L}_{S} - {L}^{′} ) ]$$

$$e {φ}_{F} ( y ) = e {φ}_{F 0}$$

At the same time, the length L_{D} of (3) the drain-side region can also be determined as follows using the following formula.

$$2 kT Ln Cos [ \frac{1}{{c}_{D}} \sqrt{\frac{{e}^{2} {n}_{s}^{D}}{2 ɛ kT}} {L}_{D} ] = - {ev}^{D}$$

$${L}_{D} = {L}_{D}^{OS} = {c}_{D} \sqrt{\frac{2 ɛ kT}{{e}^{2} {n}_{s}^{D}}} ArcCos \{ Exp [ - \frac{{v}^{D}}{2 kT} ] \}$$

Here, the depletion layer width L_{D}^{Si} of the drain-side region of the transistor using a silicon semiconductor and the length L_{D}^{OS} of the drain-side region of the transistor using an oxide semiconductor are compared with each other.

$${L}_{D}^{Si} = \sqrt{1 + \frac{{V}_{SD}^{D}}{{v}^{D}}} \times \sqrt{\frac{2 ɛ {v}^{D}}{{eN}_{A}}}$$

$$( where {v}^{D} = {v}^{D ( Si )} ≡ \frac{{E}_{g ( Si )}}{2 e} + {φ}_{F 0} - {φ}_{s}^{D} )$$

$${L}_{D}^{OS} = \sqrt{1 + \frac{{V}_{SD}^{D}}{{v}^{D}}} \times \sqrt{\frac{2 ɛ kT}{{e}^{2} {n}_{s}^{D}}} ArcCos \{ Exp [ - \frac{{v}^{D}}{2 kT} ] \}$$

$$( where {v}^{D} = {v}^{D ( OS )} ≡ \frac{{E}_{g ( OS )}}{2 e} + {φ}_{F 0} - {φ}_{s}^{D} )$$

In the case of the transistor using an oxide semiconductor, the length L_{D}^{OS} of the drain-side region is proportional to (kT)^{1/2}, whereas in the case of the transistor using a silicon semiconductor, the depletion layer width L_{D}^{Si} of the drain-side region is proportional to (ev^{D})^{1/2}. In general, kT<ev^{D} of is satisfied at room temperature. In addition, an oxide semiconductor has a larger band gap than a silicon semiconductor, and thus v^{D(Si)}<v^{D(OS)} is satisfied. Considering these described above and the fact that V_{SD}^{D} approximates V_{SD} in the subthreshold region, the depletion layer width L_{D}^{Si} of the drain-side region of the silicon semiconductor is more sensitive to a change in the drain voltage V_{SD} and has larger dependence on the drain voltage V_{SD}. In other words, the DIBL effect can be further suppressed in the oxide semiconductor.

Next, a surface steady-state current density Jₛ of a general semiconductor layer and a voltage drop V_{SD}^{S} in a source-side region of the semiconductor layer are derived. This is because a punch-through current can be estimated by deriving Jₛ, and the extent of the DIBL effect can be presumed by deriving V_{SD}^{S}.

The derived Jₛ and V_{SD}^{S} are applied to the oxide semiconductor and the silicon semiconductor. These values are represented graphically to check which of the oxide semiconductor having an (n⁺)-(n) junction and the silicon semiconductor having an (n⁺)-(p) bond has higher resistance to a short-channel effect.

First, the obtained potential φ and Fermi potential φ_{F} are substituted into a charge transfer equation, thereby deriving a relation between the voltage drop V_{SD}^{S} in the source-side region and the surface steady-state current density Jₛ and a relation between the voltage drop V_{SD}^{D} in the drain-side region and the surface steady-state current density Jₛ.

A method for deriving the voltage drop V_{SD}^{S} in the source-side region is described below.

The following formula is obtained according to the charge transfer equation.

$$\frac{\partial {φ}_{F}}{\partial y} = - \frac{{J}_{s}}{μ en} \qquad ( 5 )$$

When both sides of the above formula are integrated in a range of y=[0, L_{S}], the voltage drop V_{SD}^{S} in the source-side region is obtained from the left side of Formula (5).

$${\int }_{0}^{{L}_{S}} \frac{\partial {φ}_{F}}{\partial y} \partial y = {V}_{SD}^{S}$$

On the other hand, from the right side of Formula (5), the following calculation can be conducted.

$$\begin{matrix}\begin{matrix}- {\int }_{0}^{{L}_{S}} \frac{{J}_{s}}{μ en} \partial y = - \frac{{J}_{s}}{μ {en}_{s}^{S}} {\int }_{0}^{{L}_{S}} {Cos}^{2} [ \frac{1}{{c}_{S}} \sqrt{\frac{{e}^{2} {n}_{s}^{S}}{2 ɛ kT}} ( y - {L}_{S} ) ] \partial y \\ = - \frac{{J}_{s}}{μ {en}_{s}^{S}} {\int }_{0}^{{L}_{S}} \frac{1}{2} ( 1 + Cos [ \frac{2}{{c}_{S}} \sqrt{\frac{{e}^{2} {n}_{s}^{S}}{2 ɛ kT}} ( y - {L}_{S} ) ] ) \partial y \\ = - {\frac{{J}_{s}}{μ {en}_{s}^{S}} [ \frac{1}{2} ( y + \frac{{c}_{S}}{2} \sqrt{\frac{2 ɛ kT}{{e}^{2} {n}_{s}^{S}}} Sin [ \frac{2}{{c}_{S}} \sqrt{\frac{{e}^{2} {n}_{s}^{S}}{2 ɛ kT}} ( y - {L}_{S} ) ] ) ]}_{0}^{{L}_{S}} \\ = - \frac{{J}_{s}}{μ {en}_{s}^{S}} \frac{{L}_{S}}{2} ( 1 + \frac{Sin 2 {θ}_{S}}{2 {θ}_{S}} )\end{matrix} \\ ( where {θ}_{S} = ArcCos \{ Exp [ - \frac{{v}^{S}}{2 kT} ] \} )\end{matrix}$$

Therefore, V_{SD}^{S} can be represented as follows using Jₛ. Note that fₛ is a numerical factor of approximately ½≦f_{S}≦1.

$${V}_{SD}^{S} = - \frac{{J}_{s}}{μ {en}_{s}^{S}} {L}_{S} {f}_{S} \\ ( where {f}_{S} ≡ \frac{1}{2} ( 1 + \frac{Sin 2 {θ}_{S}}{2 {θ}_{S}} ) )$$

A method for deriving the voltage drop V_{SD}^{D} in the drain-side region is described below.

Both sides of Formula 84 are integrated in a range of y=[L_{S}+L′, L], whereby the voltage drop V_{SD}^{D} in (3) the drain-side region is obtained as follows from the left side of Formula (5).

$${\int }_{{L}_{S} + {L}^{′}}^{L} \frac{\partial {φ}_{F}}{\partial y} \partial y = {V}_{SD}^{D}$$

On the other hand, from the right side of Formula 84, the following calculation can be conducted.

$$\begin{matrix}\begin{matrix}- {\int }_{{L}_{S} + {L}^{′}}^{L} \frac{{J}_{s}}{μ en} \partial y = - \frac{{J}_{s}}{μ {en}_{s}^{D}} {\int }_{{L}_{S} + {L}^{′}}^{L} {Cos}^{2} [ \frac{1}{{c}_{D}} \sqrt{\frac{{e}^{2} {n}_{s}^{D}}{2 ɛ kT}} ( y - {L}_{S} - {L}^{′} ) ] \partial y \\ = - \frac{{J}_{s}}{μ {en}_{s}^{D}} {\int }_{{L}_{S} + {L}^{′}}^{L} \frac{1}{2} ( 1 + Cos [ \frac{2}{{c}_{D}} \sqrt{\frac{{e}^{2} {n}_{s}^{D}}{2 ɛ kT}} ( y - {L}_{S} + {L}^{′} ) ] ) \partial y \\ = - {\frac{{J}_{s}}{μ {en}_{s}^{D}} [ \frac{1}{2} ( \begin{matrix}y + \frac{{c}_{D}}{2} \sqrt{\frac{2 ɛ kT}{{e}^{2} {n}_{s}^{D}}} \\ Sin [ \frac{2}{{c}_{D}} \sqrt{\frac{{e}^{2} {n}_{s}^{D}}{2 ɛ kT}} ( y - {L}_{S} - {L}^{′} ) ]\end{matrix} ) ]}_{{L}_{S} + {L}^{′}}^{L} \\ = - \frac{{J}_{s}}{μ {en}_{s}^{D}} \frac{{L}_{D}}{2} ( 1 + \frac{Sin 2 {θ}_{D}}{2 {θ}_{D}} )\end{matrix} \\ ( where {θ}_{D} = ArcCos \{ Exp [ - \frac{{v}^{D}}{2 kT} ] \} )\end{matrix}$$

Therefore, V_{SD}^{D} can be represented as follows using Jₛ. Note that f_{D} is a numerical factor of approximately ½≦f_{D}≦1.

$${V}_{SD}^{D} = - \frac{{J}_{s}}{μ {en}_{s}^{D}} {L}_{D} {f}_{D} \\ ( where {f}_{D} ≡ \frac{1}{2} ( 1 + \frac{Sin 2 {θ}_{D}}{2 {θ}_{D}} ) )$$

Next, a relation between the voltage drop V_{SD}′ in the effective channel region and the surface steady-state current density Jₛ is derived.

A method for deriving the surface steady-state current density Jₛ is described below.

Here, the subthreshold region (the gate voltage V_{G}≦the threshold voltage Vₜₕ) is examined as a region where the DIBL effect is significantly shown; therefore, a punch-through current in the state where the transistor is off is to be derived. In the subthreshold region (V_{G}≦Vₜₕ), even if the drain voltage V_{SD} is finite, a relation of the potential φ(0, y) of the effective channel region=φ_{const} (constant)≡φ_{S0} can be regarded as being satisfied. Therefore, also in the case of y=L_{S} and y=L_{S}+L′, a relation of φ(0, y)=φ_{S0} is satisfied (φ(0, L_{S})=φ_{S0}, and φ(0, L_{S}+L′=φ_{S0}); therefore, the following relation is obtained.

φₛ₀=φₛ^{S}+V_{SD}^{S}=φₛ^{D}+V_{SD}^{S}+V_{SD}′

In addition, the following relation is also obtained in terms of electron density.

$${n}_{s 0} = {n}_{s}^{S} Exp [ \frac{e {V}_{SD}^{S}}{kT} ] = {n}_{s}^{D} Exp [ \frac{e ( {V}_{SD}^{S} + {V}_{SD}^{′} )}{kT} ]$$

$$( where {n}_{s 0} = {n}_{i} Exp [ \frac{e ( {φ}_{s 0} - {φ}_{F 0} )}{kT} ] )$$

To derive the relation between the voltage drop V_{SD}′ in the effective channel region and the surface steady-state current density Jₛ, when both sides of the change transfer equation are integrated in a range of y=[Lₛ, Lₛ+L′], the following calculation is conducted.

$$\begin{matrix}{J}_{s} {\int }_{{L}_{S}}^{{L}_{S} + {L}^{′}} \partial y = - μ {en}_{i} {\int }_{{L}_{S}}^{{L}_{S} + {L}^{′}} Exp [ - \frac{e ( {φ}_{s 0} - {φ}_{F} )}{kT} ] \frac{\partial {φ}_{F}}{\partial y} \partial y \\ = μ {kTn}_{i} Exp [ \frac{e {φ}_{s 0}}{kT} ] {\int }_{{L}_{S}}^{{L}_{S} + {L}^{′}} \frac{\partial }{\partial y} Exp [ - \frac{e {φ}_{F}}{kT} ] \partial y \\ = μ {kTn}_{i} Exp [ \frac{e {φ}_{s 0}}{kT} ] {\{ Exp [ - \frac{e {φ}_{F}}{kT} ] \}}_{{L}_{S}}^{{L}_{S} + {L}^{′}} \\ = - μ {kTn}_{s 0} Exp [ - \frac{e {V}_{SD}^{S}}{kT} ] ( 1 - Exp [ - \frac{e {V}_{SD}^{′}}{kT} ] ) \\ = - μ {kTn}_{s}^{S} ( 1 - Exp [ - \frac{e {V}_{SD}^{′}}{kT} ] )\end{matrix}$$

Accordingly, the following relation is derived.

$${J}_{s} = - \frac{μ {kTn}_{s}^{S}}{{L}^{′}} ( 1 - Exp [ - \frac{e {V}_{SD}^{′}}{kT} ] )$$

From the relation between the voltage drop V_{SD}^{S} in the source-side region and the surface steady-state current density Jₛ, the relation between the voltage drop V_{SD}^{D} in the drain-side region and the surface steady-state current density Jₛ, and the relation between the voltage drop V_{SD}′ in the effective channel region and the surface steady-state current density Jₛ, which are described above, V_{SD}^{S}, V_{SD}^{D}, and Jₛ each can be represented as follows in the case of the oxide semiconductor.

$${V}_{SD}^{S} = - \frac{{J}_{s}}{μ {en}_{s}^{S}} {L}_{S} {f}_{S}$$

$${V}_{SD}^{D} = - \frac{{J}_{s}}{μ {en}_{s}^{D}} {L}_{D} {f}_{D}$$

$${J}_{s} = - \frac{μ {kTn}_{s}^{S}}{{L}^{′}} ( 1 - Exp [ - \frac{e {V}_{SD}^{′}}{kT} ] )$$

. . . collectively set as (A).

In the case of the silicon semiconductor, Jₛ can be represented as follows.

$${J}_{s} = - \frac{μ kT}{{L}_{A}} {n}_{s}^{D} ( 1 - Exp [ - \frac{e {V}_{SD}^{D}}{kT} ] )$$

$${J}_{s} = - \frac{μ {en}_{s}^{S}}{{L}_{A}} {V}_{SD}^{S}$$

$${J}_{s} = - \frac{μ {kTn}_{s}^{S}}{{L}^{′}} ( 1 - Exp [ - \frac{e {V}_{SD}^{′}}{kT} ] )$$

. . . collectively set to as (A)′.

When a surface steady-state current density Jₛ^{OS} of the oxide semiconductor layer is derived using the formulae (A), the following formula is obtained.

$${J}_{s}^{OS} = - \frac{μ {en}_{s}^{S} {V}_{SD}^{D}}{{f}_{D} {L}_{D} + {L}^{′} \frac{e {V}_{SD}^{D}}{kT}}$$

Similarly, when the voltage drop V_{SD}^{S} in the source-side region of the oxide semiconductor layer is derived using the formulae (A), the following formula is obtained.

$${V}_{SD}^{S} = \frac{kT}{e} \frac{{f}_{s} {L}_{s} {v}_{SD}}{{f}_{D} {L}_{D} + {L}^{′} {v}_{SD}}$$

Similarly, when the voltage drop V_{SD}′ in the effective channel region of the oxide semiconductor layer is derived using the formulae (A), the following formula is obtained.

$${V}_{SD}^{′} = \frac{kT}{e} \frac{{L}^{′} {v}_{SD}}{{f}_{D} {L}_{D} + {L}^{′} {v}_{SD}}$$

Similarly, when the voltage drop V_{SD}^{D} in the drain-side region of the oxide semiconductor layer is derived using the formulae (A), the following formula is obtained.

$${V}_{SD}^{D} = {V}_{SD} - \frac{kT}{e} ( 1 + \frac{{f}_{S} {L}_{S}}{{L}^{′}} ) \frac{{L}^{′} {v}_{SD}}{{f}_{D} {L}_{D} + {L}^{′} {v}_{SD}}$$

Note that here, the following is set: v_{SD}≡(eV_{SD})/kT. In addition, a term of (1/v_{SD})²˜0 is ignored during the derivation in view of eV_{SD}>>kT. In addition, according to eV_{SD}>>kT, V_{SD}^{D} can approximate V_{SD}, V_{SD}^{S} can approximate 0V, and V_{SD}′ can approximate 0V.

Therefore, in the subthreshold region (V_{G}≦Vₜₕ), the drain voltage V_{SD} largely drops in the drain-side region. Therefore, when V_{SD}^{D} is replaced with V_{SD}, as a result, the surface steady-state current density Jₛ^{OS} of the oxide semiconductor layer can be represented as follows.

$${J}_{s}^{OS} = - \frac{μ {en}_{s}^{S} {V}_{SD}}{{f}_{D} {L}_{D} + {L}^{′} {v}_{SD}}$$

In the case of the oxide semiconductor having the (n⁺)-(n) junction, the surface steady-state current density Jₛ^{OS} and the voltage drop V_{SD}^{D} in the source-side region are each represented as follows (see FIG. 3, FIG. 4, FIG. 5, and FIG. 6).

$${J}_{s}^{OS} = - \frac{μ {en}_{s}^{S} {V}_{SD}}{{f}_{D} {L}_{D} + {L}^{′} {v}_{SD}}$$

$${V}_{SD}^{S} = \frac{kT}{e} \frac{{f}_{s} {L}_{s} {v}_{SD}}{{f}_{D} {L}_{D} + {L}^{′} {v}_{SD}}$$

Note that the following is set in the drawings: f_{S}=f_{D}=½ and θ_{S}=θ_{D}=π/2.

When a surface steady-state current density Jₛ^{Si} of the silicon semiconductor layer is derived using the formulae (A)′, the following formula is obtained.

$${J}_{s}^{Si} = - \frac{μ {kTn}_{s}^{S}}{{L}^{′} + {L}_{A}}$$

$$( where {L}_{A} ≡ f \sqrt{\frac{2 ɛ kT}{{e}^{2} {N}_{A}}} , f ≡ {\int }_{0}^{a} Exp [ - {t}^{2} ] d t )$$

Note that f is a numerical factor of approximately 0<f<(π)^{1/2}/2.

Similarly, when the voltage drop V_{SD}^{S} in the source-side region of the silicon semiconductor layer is derived using the formulae (A)′, the following formula is obtained.

$${V}_{SD}^{S} = \frac{kT}{e} Ln ( 1 + \frac{{L}_{A}}{{L}^{′}} )$$

Similarly, when the voltage drop V_{SD}′ in the effective channel region of the silicon semiconductor layer is derived using the formulae (A)′, the following formula is obtained.

$${V}_{SD}^{′} = \frac{kT}{e} Ln ( 1 + \frac{{L}^{′}}{{L}_{A}} )$$

Similarly, when the voltage drop V_{SD}^{D} in (3) the drain-side region of the silicon semiconductor layer is derived using the formulae (A)′, the following formula is obtained.

$${V}_{SD}^{D} = {V}_{SD} - \frac{kT}{e} Ln ( 2 + \frac{{L}_{A}}{{L}^{′}} + \frac{{L}^{′}}{{L}_{A}} )$$

When eV_{SD}^{D}>>kT, V_{SD}^{D} can approximate V_{SD}, V_{SD}^{S} can approximate 0 V, and V_{SD}′ can approximate 0 V, and in a similar manner to that in the case of the oxide semiconductor layer, the drain voltage V_{SD} largely drops in (3) the drain-side region in the subthreshold region also in the case of the silicon semiconductor.

In the case of the oxide semiconductor having the (n⁺)-(p) junction, the surface steady-state current density Jₛ^{Si} and the voltage drop V_{SD}^{D} in the source-side region are each represented as follows (see FIG. 3, FIG. 4, FIG. 5, and FIG. 6).

$${J}_{s}^{Si} = - \frac{μ {kTn}_{s}^{S}}{{L}^{′} + {L}_{A}}$$

$${V}_{SD}^{S} = \frac{kT}{e} Ln ( 1 + \frac{{L}_{A}}{{L}^{′}} )$$

Note that the following is set in the drawings: f=1.

Next, the DIBL effect and influence of the DIBL effect upon the punch-through current are examined from the derived surface steady-state current density Jₛ and the voltage drop V_{SD}^{S} in the source-side region by comparing the oxide semiconductor with the silicon semiconductor.

FIG. 3 shows drain voltage V_{SD} dependence of the surface steady-state current density Jₛ. FIG. 4 shows drain voltage V_{SD} dependence of the voltage drop V_{SD}^{S} in the source-side region. FIG. 5 shows channel length L dependence of the surface steady-state current density Jₛ. FIG. 6 shows channel length L dependence of the DIBL effect.

Parameters in FIG. 3 and FIG. 4 are as follows: the channel length L=1 μm; two standards of carrier density, n₀=1.0×10¹⁶/cm³ and n₀=1.0×10¹⁷/cm³; the band gap E_{g} of the oxide semiconductor=3.2 eV; and the band gap E_{g} of the silicon semiconductor=1.1 eV. Note that the followings are common parameters: the dielectric constant ∈=10∈₀; the absolute temperature T=300 K; the intrinsic electron density nᵢ=1.0×10¹¹/cm³. In addition, Jₛ is normalized using electron mobility μ.

Here, the surface steady-state current density Jₛ^{OS} of the oxide semiconductor and the surface steady-state current density Jₛ^{Si} of the silicon semiconductor are compared to each other. FIG. 3 shows that the surface steady-state current density Jₛ^{OS} of the oxide semiconductor has smaller drain voltage V_{SD} dependence than the surface steady-state current density Jₛ^{Si} of the silicon semiconductor. In particular, when the drain voltage V_{SD} is increased, the difference is significantly shown.

In addition, FIG. 4 shows that the influence of the DIBL effect upon the silicon semiconductor is larger than that of the DIBL effect upon the oxide semiconductor in the case where the silicon semiconductor and the oxide semiconductor have the same carrier density. In addition, as the drain voltage V_{SD} is increased, the influence of the DIBL effect upon the silicon semiconductor becomes larger. Therefore, FIG. 3 and FIG. 4 suggest that degradation of the characteristics of the transistor due to the DIBL effect is larger in the case of the silicon semiconductor.

To examine resistance to a short-channel effect, the channel length L dependence of the surface steady-state current density Jₛ and the channel L dependence of the DIBL effect are shown in FIG. 5 and FIG. 6, respectively, where the carrier density n₀ is 1.0×10¹⁶/cm³ and the drain voltage V_{SD} is 1 V.

FIG. 5 and FIG. 6 obviously show that the surface steady-state current density Jₛ and the DIBL effect are reduced more in the oxide semiconductor than in the silicon semiconductor when the channel lengths are the same. In addition, FIG. 5 and FIG. 6 show that the minimum channel length with which the value of the steady-state current density Jₛ^{OS} can be obtained in the oxide semiconductor is small as compared to in the silicon semiconductor.

In the silicon semiconductor, when the channel length L is less than approximately 0.6 μm, the length L′ of the effective channel region (=L−L_{S}−L_{D}) becomes less than or equal to 0 owing to an increase of L_{D}, and thus the effective channel cannot be defined. In other words, when the channel length L is less than or equal to 0.6 μm, the surface steady-state current density Jₛ^{Si} of the silicon semiconductor has no value. On the other hand, in the oxide semiconductor, the length L′ of the effective channel region can be defined until the channel length L is reduced to approximately 0.2 μm. Therefore, it suggests that the oxide semiconductor which is less influenced by the DIBL effect is resistant to a short-channel effect as compared to the silicon semiconductor.

The above considerations indicate that the oxide semiconductor having the (n⁺)-(n) junction has higher resistance to a short-channel effect than the silicon semiconductor having the (n⁺)-(p) junction. Although the oxide semiconductor is used as an example of a semiconductor having an (n⁺)-(n) junction in the above investigation, the above considerations can be applied to any semiconductor as long as the semiconductor has majority carriers in a junction portion of a source and the semiconductor layer and in a junction portion of a drain and the semiconductor layer.

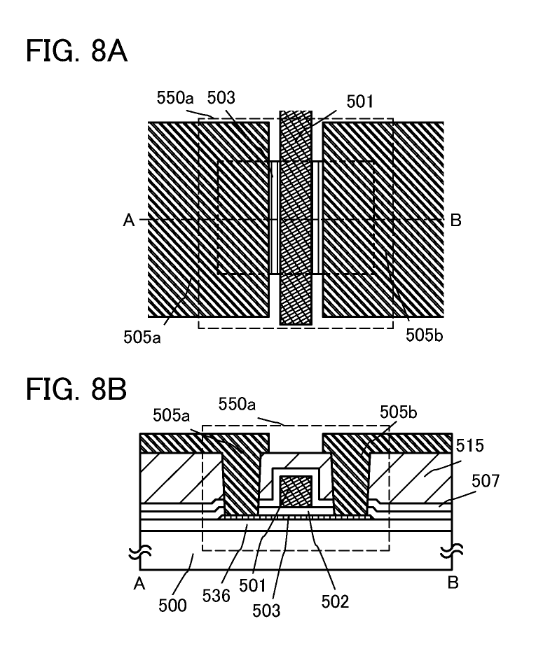

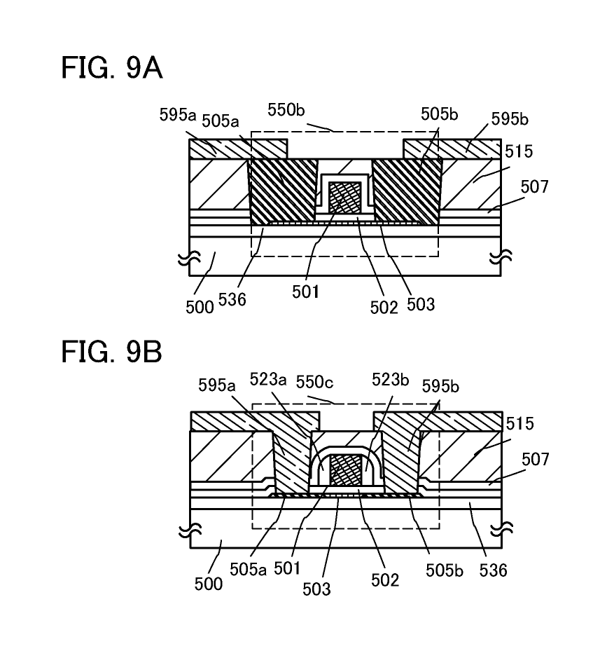

Next, structural examples of a transistor which satisfies the above relations are described using FIGS. 8A and 8B and FIGS. 9A and 9B.

The transistor preferably has a top-gate structure but may have a bottom-gate structure.

A transistor 550a illustrated in FIGS. 8A and 8B is an example of a top-gate transistor. FIG. 8A is a plan view of the transistor 550a, and FIG. 8B is a cross-sectional view taken along dashed-dotted line A-B in FIG. 8A. In FIG. 8A, some of components of the transistor 550a are omitted to avoid complexity.

As illustrated in FIG. 8B which is a cross-sectional view in the channel length direction, a semiconductor device including a transistor 550a includes, over a substrate 500 having an insulating surface provided with an insulating film 536, an oxide semiconductor film 503, a source 505a, a drain 505b, a gate insulating film 502, a gate 501, and an insulating film 507 and an interlayer insulating film 515 which are provided over the gate 501.

The channel length of the transistor 550a is preferably short. The channel length is further preferably greater than or equal to 5 nm and less than or equal to 500 nm.

FIGS. 9A and 9B illustrate transistors 550b and 550c which have other structures.

The transistor 550b illustrated in FIG. 9A is an example in which wiring layers 595a and 595b are provided in contact with the source 505a and the drain 505b, respectively. The source 505a and the drain 505b are formed so as to be embedded in the interlayer insulating film 515 and polishing treatment is performed to expose surfaces thereof. The wiring layers 595a and 595b are formed in contact with the exposed surfaces of the source 505a and the drain 505b to be electrically connected to the source 505a and the drain 505b. An opening in which the source 505a is provided and an opening in which the drain 505b is provided are formed by different steps. The openings are formed by different steps using different masks, whereby a distance between the source 505a and the drain 505b can be made smaller than the exposure limit of a photolithography step. In the case of the transistor 550b, the wiring layers 595a and 595b are formed by the same photolithography step; therefore, the distance between the wiring layer 595a and the wiring layer 595b is longer than that between the source 505a and the drain 505b.

In the transistor 550c illustrated in FIG. 9B, sidewall layers 523a and 523b are provided on sidewalls of the gate 501, and the source 505a and the drain 505b are in contact with side surfaces of the oxide semiconductor film 503 to be electrically connected to the oxide semiconductor film 503. An electrical contact region between the oxide semiconductor film 503 and each of the source 505a and the drain 505b can be closer to the gate 501, and thus such a structure can be effective in improving the on-state current characteristics of the transistor.

As a method for forming the source 505a, the drain 505b, and the oxide semiconductor film 503 in the transistor 550c, any of the following methods and the like can be used: a method in which the source 505a and the drain 505b are formed, an oxide semiconductor film is formed over the source 505a and the drain 505b, and polishing is performed until the source 505a and the drain 505b are exposed to form the oxide semiconductor film 503; a method in which the oxide semiconductor film 503 is formed, a conductive film is formed over the oxide semiconductor film 503, and polishing is performed until the oxide semiconductor film 503 is exposed to form the source 505a and the drain 505b.

For the sidewall layers 523a and 523b, an insulating material or a conductive material can be used. In the case where a conductive material is used, the sidewall layers 523a and 523b can function as part of the gate 501, and thus a region which overlaps with the source 505a or the drain 505b with the gate insulating film 502 positioned therebetween in the channel length direction can be a region where the gate overlaps with the source or the drain with the gate insulating film positioned therebetween (Lov region). Depending on the width of each of the sidewall layers 523a and 523b which are provided on the sidewalls of the gate 501 in a self aligned manner and have conductivity, the width of the Lov region can be controlled. Accordingly, a scaled-down Lov region can be processed with high accuracy.

An oxide semiconductor used for the oxide semiconductor film contains at least indium (In). In particular, the oxide semiconductor preferably contains In and zinc (Zn). In addition, as a stabilizer for reducing the variation in electric characteristics of a transistor using the oxide semiconductor, the oxide semiconductor preferably contains gallium (Ga) in addition to In and Zn. Tin (Sn) is preferably contained as a stabilizer. Hafnium (Hf) is preferably contained as a stabilizer. Aluminum (Al) is preferably contained as a stabilizer. Zirconium (Zr) is preferably contained as a stabilizer.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) may be contained.

As the oxide semiconductor, for example, any of the following can be used: indium oxide; tin oxide; zinc oxide; a two-component metal oxide such as an In—Zn-based oxide, an In—Mg-based oxide, or an In—Ga-based oxide; a three-component metal oxide such as an In—Ga—Zn-based oxide (also referred to as IGZO), an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Note that here, for example, an “In—Ga—Zn—O-based oxide” means an oxide containing In, Ga, and Zn as its main component and there is no particular limitation on the ratio of In:Ga:Zn. The In—Ga—Zn-based oxide may contain a metal element other than the In, Ga, and Zn.

Alternatively, a material represented by InMO₃(ZnO)ₘ (m>0 is satisfied, and m is not an integer) may be used as an oxide semiconductor. Note that M represents one or more metal elements selected from Ga, Fe, Mn, and Co. Alternatively, as the oxide semiconductor, a material expressed by a chemical formula, In₂SnO₅(ZnO)ₙ (n>0, n is a natural number) may be used.

For example, an In—Ga—Zn-based oxide with an atomic ratio of In:Ga:Zn=1:1:1 (=⅓:⅓:⅓), In:Ga:Zn=2:2:1 (=⅖:⅖:⅕), In:Ga:Zn=3:1:2 (=½:⅙:⅓), or any of oxides whose composition is in the neighborhood of the above compositions can be used. Alternatively, an In—Sn—Zn-based oxide with an atomic ratio of In:Sn:Zn=1:1:1 (=⅓:⅓:⅓), In:Sn:Zn=2:1:3 (=⅓:⅙:½), or In:Sn:Zn=2:1:5 (=¼:⅛:⅝), or any of oxides whose composition is in the neighborhood of the above compositions may be used.

However, without limitation to the materials given above, a material with an appropriate composition may be used as the oxide semiconductor containing indium depending on needed semiconductor characteristics (e.g., mobility, threshold voltage, and variation). In order to obtain the required semiconductor characteristics, it is preferable that the carrier concentration, the impurity concentration, the defect density, the atomic ratio between a metal element and oxygen, the interatomic distance, the density, and the like be set to appropriate values.

For example, high mobility can be obtained relatively easily in the case of using an In—Sn—Zn oxide. However, mobility can be increased by reducing the defect density in a bulk also in the case of using an In—Ga—Zn-based oxide.

Note that for example, the expression “the composition of an oxide including In, Ga, and Zn at the atomic ratio, In:Ga:Zn=a:b:c (a+b+c=1), is in the neighborhood of the composition of an oxide containing In, Ga, and Zn at the atomic ratio, In:Ga:Zn=A:B:C (A+B+C=1)” means that a, b, and c satisfy the following relation: (a−A)²+(b−B)²+(c−C)²≦r², and r may be 0.05, for example. The same applies to other oxides.

An oxide semiconductor film can be single crystal, polycrystalline (also referred to as polycrystal), or amorphous, for example. An oxide semiconductor film may be in a non-single-crystal state, for example. The non-single-crystal state is, for example, structured by at least one of c-axis aligned crystal (CAAC), polycrystal, microcrystal, and an amorphous part. The density of defect states of an amorphous part is higher than those of microcrystal and CAAC. The density of defect states of microcrystal is higher than that of CAAC.

Preferably, a CAAC-OS (c-axis aligned crystalline oxide semiconductor) film can be used as the oxide semiconductor film. In the CAAC-OS, for example, the c-axes are aligned, and a-axes and/or b-axes are not macroscopically aligned.

For example, an oxide semiconductor film may include microcrystal. Note that an oxide semiconductor film including microcrystal (also referred to as a microcrystalline oxide semiconductor film) includes, for example, an oxide semiconductor including microcrystal (also referred to as nanocrystal) with a size greater than or equal to 1 nm and less than 10 nm. Alternatively, a microcrystalline oxide semiconductor film, for example, includes an oxide semiconductor having a crystal-amorphous mixed phase structure where crystal parts (each of which is greater than or equal to 1 nm and less than 10 nm) are distributed in an amorphous phase.

For example, an oxide semiconductor film may include an amorphous part. Note that an oxide semiconductor film including an amorphous part (also referred to as an amorphous oxide semiconductor film), for example, has disordered atomic arrangement and no crystalline component. Alternatively, an amorphous oxide semiconductor film is, for example, absolutely amorphous and has no crystal part.

Note that an oxide semiconductor film may be a mixed film including any of a CAAC-OS, a microcrystalline oxide semiconductor, and an amorphous oxide semiconductor. The mixed film, for example, includes a region of an amorphous oxide semiconductor, a region of a microcrystalline oxide semiconductor, and a region of a CAAC-OS. Further, the mixed film may have a stacked structure including a region of an amorphous oxide semiconductor, a region of a microcrystalline oxide semiconductor, and a region of a CAAC-OS, for example.

Note that an oxide semiconductor film may be in a single-crystal state, for example.

An oxide semiconductor film preferably includes a plurality of crystal parts. In each of the crystal parts, a c-axis is preferably aligned in a direction parallel to a normal vector of a surface where the oxide semiconductor film is formed or a normal vector of a surface of the oxide semiconductor film. Note that, among crystal parts, the directions of the a-axis and the b-axis of one crystal part may be different from those of another crystal part. An example of such an oxide semiconductor film is a CAAC-OS film.

The CAAC-OS film is not absolutely amorphous. The CAAC-OS film includes an oxide semiconductor film with a crystal-amorphous mixed phase structure where crystal parts and amorphous parts are intermingled. Note that in most cases, the crystal part fits inside a cube whose one side is less than 100 nm. In an image obtained with a transmission electron microscope (TEM), a boundary between an amorphous part and a crystal part and a boundary between crystal parts in the CAAC-OS film are not clearly detected. Further, with the TEM, a grain boundary in the CAAC-OS film is not clearly found. Thus, in the CAAC-OS film, a reduction in electron mobility, due to the grain boundary, is suppressed.

In each of the crystal parts included in the CAAC-OS film a c-axis is aligned in a direction parallel to a normal vector of a surface where the CAAC-OS film is formed or a normal vector of a surface of the CAAC-OS film. Further, in each of the crystal parts, metal atoms are arranged in a triangular or hexagonal configuration when seen from the direction perpendicular to the a-b plane, and metal atoms are arranged in a layered manner or metal atoms and oxygen atoms are arranged in a layered manner when seem from the direction perpendicular to the c-axis. Note that, among crystal parts, the directions of the a-axis and the b-axis of one crystal part may be different from those of another crystal part. In this specification, a term “perpendicular” includes a range from 85° to 95°. In addition, a term “parallel” includes a range from −5° to 5°.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film). Note that the film deposition is accompanied with the formation of the crystal parts or followed by the formation of the crystal parts through crystallization treatment such as heat treatment. Hence, the c-axes of the crystal parts are aligned in the direction parallel to a normal vector of the surface where the CAAC-OS film is formed or a normal vector of the surface of the CAAC-OS film.

With the use of the CAAC-OS film in a transistor, change in electric characteristics of the transistor due to irradiation with visible light or ultraviolet light is small. Thus, the transistor has high reliability.

Note that part of oxygen included in the oxide semiconductor film may be substituted with nitrogen.

In an oxide semiconductor having a crystal portion such as the CAAC-OS, defects in the bulk can be further reduced and when the surface flatness of the oxide semiconductor is improved, mobility higher than that of an oxide semiconductor in an amorphous state can be obtained. In order to improve the surface planarity, the oxide semiconductor is preferably formed over a flat surface.

The oxide semiconductor film can be formed to have a thickness greater than or equal to 1 nm and less than or equal to 30 nm (preferably greater than or equal to 5 nm and less than or equal to 10 nm) by a sputtering method, a molecular beam epitaxy (MBE) method, a CVD method, a pulsed laser deposition method, an atomic layer deposition (ALD) method, or the like as appropriate. In addition, the oxide semiconductor film may be deposited using a sputtering apparatus in which deposition is performed in a state where surfaces of a plurality of substrates are set substantially perpendicularly to a surface of a sputtering target.

This application is based on Japanese Patent Application serial no. 2012-022445 filed with Japan Patent Office on Feb. 3, 2012, the entire contents of which are hereby incorporated by reference.

What is claimed is:

1. A transistor comprising:
a semiconductor layer including a channel region;
a source and a drain in contact with the semiconductor layer; and
a gate overlapping with the channel region in the semiconductor layer with a gate insulating layer interposed therebetween,
wherein the channel region includes a source-side region, an effective channel region, and a drain-side region, and
wherein a majority carrier density nₛ^{S} of the source-side region satisfies a relation of Formula (1), a majority carrier density nₛ^{D} of the drain-side region satisfies a relation of Formula (2), and the length L_{D} of the drain-side region is represented as Formula (3) where:
a length of the drain-side region is L_{D},
a voltage drop in the drain-side region is V_{SD}^{D},
a difference between an energy barrier of the drain-side region and a product of the voltage drop in the drain-side region and an elementary charge is ev^{D},
a Fermi potential at an interface between the source and the source-side region is φ_{F0},
an intrinsic electron density is nᵢ,
a surface potential at an interface between the effective channel region and the drain-side region is φₛ^{D},
a surface potential at an interface between the effective channel region and the source-side region is φₛ^{S},
a band gap of the semiconductor layer is E_{g},
a dielectric constant of the semiconductor layer is ∈,
the elementary charge is e,
a Boltzmann constant is k, and
an absolute temperature is T.
$$\begin{matrix}{n}_{i} Exp [ \frac{e ( {φ}_{s}^{S} - {φ}_{F 0} )}{kT} ] ≦ {n}_{s}^{S} ≦ {n}_{i} Exp [ \frac{{E}_{g}}{2 kT} ] & ( 1 ) \\ {n}_{i} Exp [ \frac{e ( {φ}_{s}^{D} - {φ}_{F 0} )}{kT} ] ≦ {n}_{s}^{D} ≦ {n}_{i} Exp [ \frac{{E}_{g}}{2 kT} ] & ( 2 ) \\ {L}_{D} = \sqrt{1 + \frac{{V}_{SD}^{D}}{{v}^{D}}} \sqrt{\frac{2 ɛ kT}{{e}^{2} {n}_{s}^{D}}} ArcCos \{ Exp [ - \frac{{v}^{D}}{2 kT} ] \} & ( 3 )\end{matrix}$$

2. The transistor according to claim 1, wherein a length of the channel region is greater than or equal to 5 nm and less than or equal to 500 nm.

3. The transistor according to claim 1, wherein a surface steady-state current density Jₛ is represented as Formula (4) where electron mobility is μ, a drain voltage is V_{SD}, and a length of the effective channel region is L′.
$${J}_{s} = - \frac{μ {en}_{s}^{S} {V}_{SD}}{{f}_{D} {L}_{D} + {L}^{′} {v}_{SD}} \\ ( where {f}_{D} ≡ \frac{1}{2} ( 1 + \frac{Sin 2 {θ}_{D}}{2 {θ}_{D}} ) , {v}_{SD} ≡ \frac{e {V}_{SD}}{kT} ) \qquad ( 4 )$$

4. The transistor according to claim 1, wherein the semiconductor layer comprises oxide semiconductor.

5. A semiconductor device comprising a transistor, the transistor comprising:
a semiconductor layer including a channel region;
a source and a drain in contact with the semiconductor layer; and
a gate overlapping with the channel region in the semiconductor layer with a gate insulating layer interposed therebetween,
wherein the channel region includes a source-side region, an effective channel region, and a drain-side region, and
wherein a majority carrier density nₛ^{S} of the source-side region satisfies a relation of Formula (1), a majority carrier density nₛ^{D} of the drain-side region satisfies a relation of Formula (2), and the length L_{D} of the drain-side region is represented as Formula (3) where:
a length of the drain-side region is L_{D},
a voltage drop in the drain-side region is V_{SD}^{D},
a difference between an energy barrier of the drain-side region and a product of the voltage drop in the drain-side region and an elementary charge is ev^{D},
a Fermi potential at an interface between the source and the source-side region is φ_{F0},
an intrinsic electron density is nᵢ,
a surface potential at an interface between the effective channel region and the drain-side region is φₛ^{D},
a surface potential at an interface between the effective channel region and the source-side region is φₛ^{S},
a band gap of the semiconductor layer is E_{g},
a dielectric constant of the semiconductor layer is ∈,
the elementary charge is e,
a Boltzmann constant is k, and
an absolute temperature is T.
$$\begin{matrix}{n}_{i} Exp [ \frac{e ( {φ}_{s}^{S} - {φ}_{F 0} )}{kT} ] ≦ {n}_{s}^{S} ≦ {n}_{i} Exp [ \frac{{E}_{g}}{2 kT} ] & ( 1 ) \\ {n}_{i} Exp [ \frac{e ( {φ}_{s}^{D} - {φ}_{F 0} )}{kT} ] ≦ {n}_{s}^{D} ≦ {n}_{i } Exp [ \frac{{E}_{g}}{2 kT} ] & ( 2 ) \\ {L}_{D} = \sqrt{1 + \frac{{V}_{SD}^{D}}{{v}^{D}}} \sqrt{\frac{2 ɛ kT}{{e}^{2} {n}_{s}^{D}}} ArcCos \{ Exp [ - \frac{{v}^{D}}{2 kT} ] \} & ( 3 )\end{matrix}$$

6. The semiconductor device according to claim 5, wherein a length of the channel region is greater than or equal to 5 nm and less than or equal to 500 nm.

7. The semiconductor device according to claim 5, wherein a surface steady-state current density J_{S} is represented as Formula (4) where electron mobility is μ, a drain voltage is V_{SD}, and a length of the effective channel region is L′.
$${J}_{s} = - \frac{μ {en}_{s}^{S} {V}_{SD}}{{f}_{D} {L}_{D} + {L}^{′} {v}_{SD}} \\ ( where {f}_{D} ≡ \frac{1}{2} ( 1 + \frac{Sin 2 {θ}_{D}}{2 {θ}_{D}} ) , {v}_{SD} ≡ \frac{e {V}_{SD}}{kT} ) \qquad ( 4 )$$

8. The semiconductor device according to claim 5, wherein the semiconductor layer comprises oxide semiconductor.
